(19) United States
(12) Patent Application Publication
(10) Pub. No.: US 2023/0092429 A1
(43) Pub. Date: Mar. 23, 2023

(54) HIGH DENSITY SILICON BASED CAPACITOR

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 17/483,403

(22) Filed: Sep. 23, 2021

(51) Int. Cl. H01L 29/94; H01L 49/02; H01L 29/66; H01L 21/768; H01L 23/48

(52) U.S. Cl. CPC H01L 29/945; H01L 28/60; H01L 29/66181; H01L 21/76898; H01L 23/481

(57) ABSTRACT

Disclosed are devices having a metal-insulator-metal (MIM) capacitor and methods for fabricating the devices. The MIM capacitor includes a plurality of trenches in a Silicon (Si) substrate; a porous Si surface formed in the plurality of trenches, where the porous Si surface has an irregular surface on sidewalls and bottoms of the plurality of trenches; an oxide layer conformally disposed on the porous Si surface; a first plate conformally disposed on the oxide layer; a first dielectric layer conformally disposed on the first plate; and a second plate conformally disposed on the first dielectric, where the first plate, the first dielectric layer, and the second plate, each have an irregular surface that generally conforms to the irregular surface of the porous Si surface.

### BACKGROUND OF THE DISCLOSURE

### 1. Field of the Disclosure

Aspects of the disclosure relate generally to devices including decoupling capacitors and more specifically, but not exclusively, to devices including silicon (Si) capacitors, silicon interposers and fabrication techniques thereof.

### 2. Description of the Related Art

Power supply noise mitigation is a key challenge in advanced technology nodes due to the large demand to supply large currents instantaneously. Decoupling capacitors between power and ground distribution networks are used to reduce the voltage fluctuations experienced by a logic circuit. A two times increase in a decoupling capacitor (e.g., 250 nF vs 500 nF) can reduce the PDN impedance by ten times (e.g., from 400 mΩ to 40 mΩ). However, to increase the capacitance, large capacitors are used adding cost, area and increasing leakage-power consumption.

The future trend of thinner interposers is a also a challenge for capacitance density. Thinner interposer trend (e.g., 50 micrometers (um) on current designs, trending to 30 um) can result in a reduced capacitor density by approximately forty percent, which results in increasing chip area and costs.

Accordingly, there is a need for systems, apparatuses and methods that overcome the deficiencies of conventional designs including the methods, systems and apparatuses provided herein in the following disclosure.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In accordance with the various aspects disclosed herein, at least one aspect includes an apparatus comprising a metal-insulator-metal (MIM) capacitor. The MIM capacitor includes a plurality of trenches in a Silicon (Si) substrate; a porous Si surface formed in the plurality of trenches, wherein the porous Si surface has an irregular surface on sidewalls and bottoms of the plurality of trenches; an oxide layer conformally disposed on the porous Si surface; a first plate conformally disposed on the oxide layer; a first dielectric layer conformally disposed on the first plate; and a second plate conformally disposed on the first dielectric, wherein the first plate, the first dielectric layer, and the second plate, each have an irregular surface that generally conforms to the irregular surface of the porous Si surface.

In accordance with the various aspects disclosed herein, at least one aspect includes a method for fabricating an apparatus comprising a metal-insulator-metal (MIM) capacitor. The method includes forming plurality of trenches in a Silicon (Si) substrate; forming a porous Si surface in the plurality of trenches, wherein the porous Si surface has an irregular surface on sidewalls and bottoms of the plurality of trenches; depositing an oxide layer conformally on the porous Si surface; depositing a first plate conformally on the oxide layer; depositing a first dielectric layer conformally on the first plate; and depositing a second plate conformally on the first dielectric, wherein the first plate, the first dielectric layer, and the second plate, each have an irregular surface that generally conforms to the irregular surface of the porous Si surface.

Other features and advantages associated with the apparatus and methods disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a partial cross-sectional view of an apparatus in accordance with one or more aspects of the disclosure.

FIG. 2 illustrates a partial cross-sectional view of an apparatus in accordance with one or more aspects of the disclosure.

FIG. 3 illustrates a partial cross-sectional view of an apparatus in accordance with one or more aspects of the disclosure.

FIG. 4 illustrates a partial cross-sectional view of an apparatus in accordance with one or more aspects of the disclosure.

FIGS. 5A-5H illustrate portions of a fabrication process in accordance with one or more aspects of the disclosure.

FIG. 6 illustrates a flowchart of a method for manufacturing a device in accordance with one or more aspects of the disclosure.

FIG. 7 illustrates an exemplary mobile device in accordance with one or more aspects of the disclosure.

FIG. 8 illustrates various electronic devices that may be integrated with any of the aforementioned devices in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

The various inventive aspects disclosed herein include metal-insulator-metal (MIM) capacitors in deep trench configurations. As used herein, the term MIM capacitor is not limited to two metal plates and a dielectric layer or any specific number of metal layers or plates and dielectric layers, but generally refers to any number (e.g., MIMIM capacitors, etc.). The MIM capacitors are embedded in localized porous Silicon tubs. The MIM capacitors can be integrated in a Silicon interposer, for example, with through-silicon vias (TSV), fine-pitch interconnects for chip-on-wafer-on substrate (CoWoS) integration.

The trench MIM capacitor formed in a localized porous Si tub provides for random pores and depressions along the trench sidewalls and bottom. As a result, this configuration provides a much larger surface area to volume ratio, which provides capacitor density increases of up to two times. The size of the pores in the Si tub is determined by electrochemical etch parameters (e.g., current, time, and Hydrofluoric (HF) acid concentration) and substrate doping. These variables provide additional design parameters to optimize the MIM capacitor design for capacitor density, process control (depth conformality, variation) and mechanical stability.

In some aspects, TSV outside of porous Si tubs allows for the MIM capacitor integration on a Si interposer and for capacitor placement in close proximity to the die/system on chip (SoC). A fifty percent increase in capacitance density allows for maintaining capacitor density even while reducing the thickness of the interposer from 50um to 30um, for example. This makes it possible to place the MIM capacitor directly below a critical component (e.g., Application Processor (AP)) and to provide a significant reduction in voltage variations/droops (e.g., due to L di/dt).

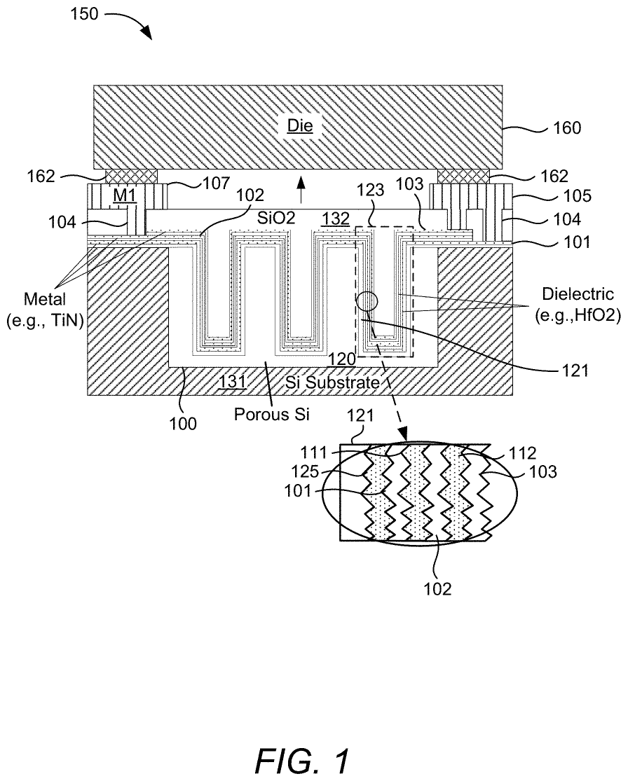

FIG. 1 illustrates a cross-sectional view of an apparatus 150 including a MIM capacitor 100 which can include a plurality of trenches 123 with a porous Silicon (Si) surface 121 formed in the plurality of trenches 123. The porous Si surface 121 has an irregular surface (e.g., pores and depressions) on sidewalls and bottoms of the plurality of trenches 123. An oxide layer 125 (e.g., Silicon Oxide (SiO2)) conformally disposed on the porous Silicon (Si) surface 121, which may form a first passivation liner. It will be appreciated, as illustrated in the detailed portion, each layer is disposed in a generally conformal manner, so that the subsequent layer will follow the irregular configuration of the porous Si surface 121. A first plate 102 is conformally disposed on the oxide layer 125. The MIM capacitor 100 can also include a first dielectric layer 111 (or insulator layer) conformally disposed on the first plate 101 and a second plate 102 conformally disposed on the first dielectric layer 111. The first plate 101, first dielectric layer 111, and second plate 102, each have an irregular surface that generally conforms to the irregular surface 121 of the Si surface, as discussed above.

The capacitor 100 can further include a second dielectric layer 112 (or insulator layer) conformally disposed on the second plate 102 and a third plate 103 conformally disposed on the second dielectric layer 112. The porous Si surface 121 is formed in a tub portion 120 comprising a porous Si material of a Si substrate 131. The plurality of trenches 123 is formed in the Si substrate 131 and the tub portion 120 of the Si substrate 131 containing the plurality of trenches 123 is processed (e.g., by electrochemical etch) to form the porous Si material.

A first electrode 105 of the MIM capacitor 100 can be coupled to the first plate 101 and the third plate 103 by one or more vias 104 that extend through an interlayer dielectric (ILD) layer 132 (e.g., SiO2) that covers the MIM capacitor 100. A second electrode 107 of the MIM capacitor 100 can be coupled to the second plate 102 by one or more vias 104 that extend through the ILD layer 132. The first electrode 105 and second electrode 107 can be coupled to die contacts 162 of die 160. The die contacts 162 may be any suitable electrical contact such as die bumps, pillars, solder balls and the like. In some aspects, the die contacts 162 are coupled to the electrodes (105, 107) of the MIM capacitor 100 by a Copper (Cu) to Copper (Cu) hybrid bond.

The first plate 101, second plate 102, third plate 103, vias 104, and other metal or conductive structures disclosed herein may be formed from any high conductive material, such as, a metal, Titanium Nitride (TiN), Titanium (Ti), Copper (Cu), Aluminum (AL), Silver (Ag), Gold (Au) or other conductive materials, alloys or combinations thereof. The first dielectric layer 111 and second dielectric layer 112 may be a high dielectric constant (high-k) dielectric material, such as Hafnium oxides (HfOₓ) or similar materials.

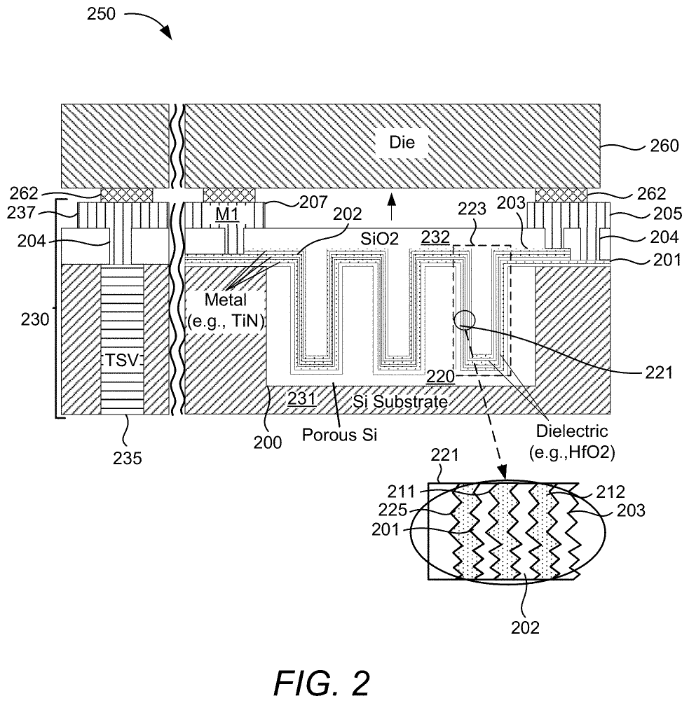

FIG. 2 illustrates a cross-sectional view of an apparatus 250 including a Si interposer 230 with the MIM capacitor 200 and the Si substrate 231 forming part of the Si interposer 230. The Si interposer 230 has plurality of interposer top contacts 237 which can be coupled to die contacts 262 to provide an electrical connection to the die 260. The die contacts 262 may be any suitable electrical contact such as die bumps, pillars, solder balls and the like. A via 204 through the ILD layer 232 may couple the interposer top contact 237 to TSV 235 to allow for an electrical connection from the die 260 through the interposer 230. The MIM capacitor 200 can be a decoupling capacitor disposed immediately below the die 260, which provides for power conditioning for the die 260, as discussed herein. The MIM capacitor 200 may be similar to MIM capacitor 100.

MIM capacitor 200 can include a plurality of trenches 223 with a porous Silicon (Si) surface 221 formed in the plurality of trenches 223. The porous Si surface 221 has an irregular surface on sidewalls and bottoms of the plurality of trenches 223. An oxide layer 225 (e.g., Silicon Oxide (SiO2)) conformally disposed on the porous Silicon (Si) surface 221. It will be appreciated, as illustrated in the detailed portion, each layer is disposed in a generally conformal manner, so that the subsequent layer will follow the irregular configuration of the porous Si surface 221. A first plate 202 is conformally disposed on the oxide layer 225. The MIM capacitor 200 can also include a first dielectric layer 211 (or insulator layer) conformally disposed on the first plate 201 and a second plate 202 conformally disposed on the first dielectric layer 211. The first plate 201, first dielectric layer 211, and second plate 202, each have an irregular surface that generally conforms to the irregular surface 221 of the Si surface, as discussed above.

The capacitor 200 can further include a second dielectric layer 212 (or insulator layer) conformally disposed on the second plate 202 and a third plate 203 conformally disposed on the second dielectric layer 212. The porous Si surface 221 is formed in a porous Si tub portion 220 comprising a porous Si material of a Si substrate 231. The plurality of trenches 223 is formed in the Si substrate 231 and the tub portion 220 of the Si substrate 231 containing the plurality of trenches 223 is processed (e.g., by electrochemical etch) to form the porous Si material.

A first electrode 205 of the MIM capacitor 200 can be coupled to the first plate 201 and the third plate 203 by one or more vias 204 that extend through an ILD layer 232 (e.g., SiO2) that covers the MIM capacitor 200. A second electrode 207 of the MIM capacitor 200 can be coupled to the second plate 202 by one or more vias 204 that extend through the ILD layer 232. The first electrode 205 and second electrode 207 can be coupled to die contacts 262 of die 260. The die contacts 262 may be any suitable electrical contact such as die bumps, pillars, solder balls and the like. In some aspects, the die contacts 262 are coupled to the electrodes (205, 207) of the MIM capacitor 200 by a Cu to Cu hybrid bond. Further, the Si interposer 230 may be coupled to the die contacts 262 by Cu to Cu hybrid bonding.

The first plate 201, second plate 202, plate 203, vias 204, and other metal or conductive structures disclosed herein may be formed from any high conductive material, such as, a metal, Titanium Nitride (TiN), Titanium (Ti), Copper (Cu), Aluminum (AL), Silver (Ag), Gold (Au) or other conductive materials, alloys or combinations thereof. The first dielectric layer 211 and second dielectric layer 212 may be a high dielectric constant (high-k) dielectric material, such as Hafnium oxides (HfOₓ) or similar materials.

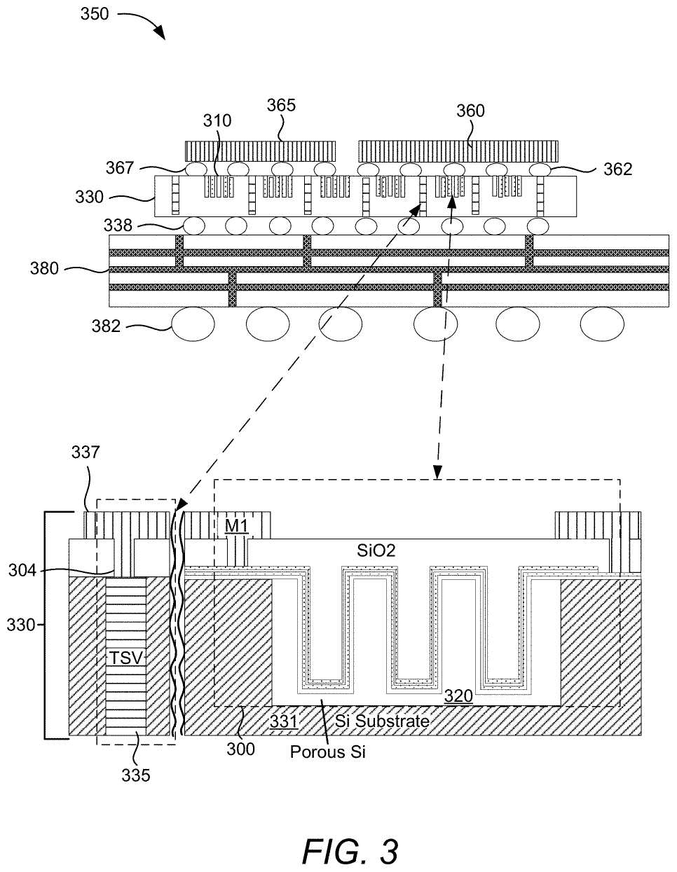

FIG. 3 illustrates a cross-sectional view of an apparatus 350 including a Si interposer 330 with the MIM capacitor 300 and the Si substrate 331 forming part of the Si interposer 330. The Si interposer 330 has a plurality of interposer top contacts 337 which can be coupled to die contacts 362 to provide an electrical connection to the die 360. The die contacts 362 may be any suitable electrical contact such as die bumps, pillars, solder balls and the like. A via 304 may couple the interposer top contact 337 to TSV 335 to allow for an electrical connection from the die 360 through the interposer 330. The MIM capacitor 300 can be a decoupling capacitor disposed immediately below the die 360, which provides for power conditioning for the die 360, as discussed herein. The MIM capacitor 300 may be similar to MIM capacitors 100 and 200 having trenches formed in a porous Si tub portion 320, except that there are only two plates in the MIM capacitor 300.

Additionally, it will be appreciated that the Si interposer 330 may be coupled to more than one die. For example, one die may be a system on chip (SoC) and another die may be a memory. However, it will be appreciated that the various aspects disclosed are not limited to any specific number or type of dies. As illustrated in FIG. 3, a second die 365 may be coupled to the Si interposer 330 via the plurality of interposer top contacts 337, which can be coupled to second die contacts 367 to provide an electrical connection to the second die 365. The second die contacts 367 may be any suitable electrical contact such as die bumps, pillars, solder balls and the like. A portion of the plurality of TSVs 335 allow for an electrical connection from the second die 365 through the interposer 330, similar to the connections for die 360 discussed in the foregoing. Likewise, the interposer may include a plurality of MIM capacitors formed similar to MIM capacitor 300. For example, MIM capacitor 310 can be configured as a decoupling capacitor and disposed immediately below the second die 365 to provide power conditioning for the second die 365. The MIM capacitor 310 may be similar to MIM capacitors 100, 200 and 300.

The Si interposer 330 may have a plurality of interposer bottom connectors 338. The bottom connectors 338 may be a bump, solder ball, pins, or any suitable electrical connection configuration. In some aspects, the bottom connectors 338 are coupled to a package substrate 380, which may include one or more metal layers to allow for routing of signals and power from the one or more dies (e.g., die 360 and second die 365) to each other and/or to one or more external components, such as, a printed circuit board, a larger package device, etc. In some aspects, the package substrate 380 also fans out the connections to allow for the spacing between the package connectors 382 (e.g., solder balls, ball grid array (BGA), pillars, pins, etc.) to be greater than the spacing of the bottom connectors 338. In some aspects, the die 360 and second die 365 are coupled to the MIM capacitor, the second MIM capacitor, respectively, and to the Si interposer by a Copper to Copper hybrid bond.

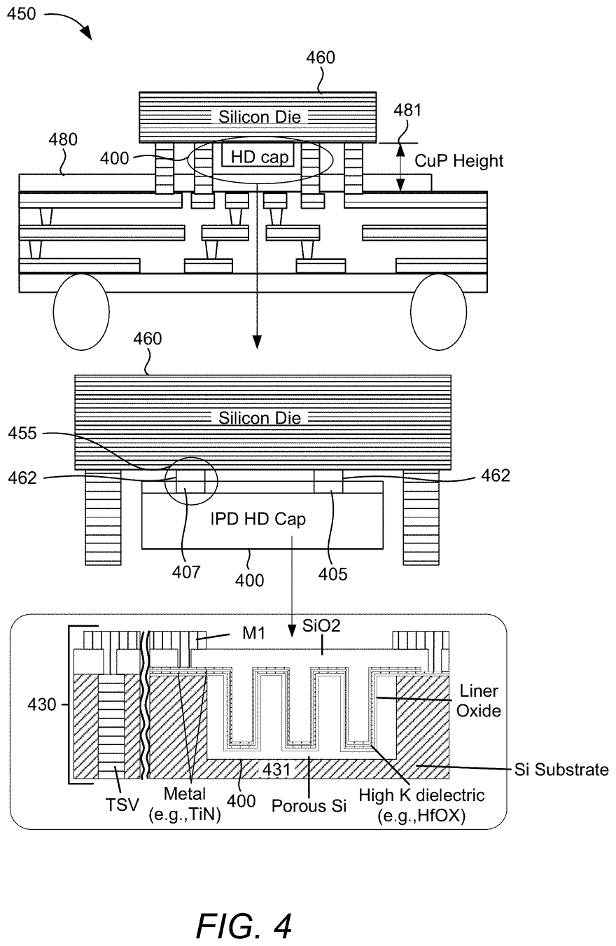

FIG. 4 illustrates a cross-sectional view of an apparatus 450 including a MIM capacitor 400 coupled to a die 460 that is coupled to a package substrate 480. As illustrated, the MIM capacitor 400 can fit within the copper pillar (CuP) height 481. In some aspects the height 481 may be on the order of 55 um to 70 um. The MIM capacitor 400 may be similar to MIM capacitors 100, 200 and 300, so a detailed description will not be provided. In some aspects the MIM capacitor 400 is less 30 microns thick, but still can provide adequate capacitance for decoupling. Having a thickness less than 30 um allows the MIM capacitor 400 to fit directly underneath the die/application processor. The MIM capacitor 400, in some aspects, may have a length on the order of 0.5 mm to 1 mm and a width on the order of 0.5 mm to 1 mm. The MIM capacitor 400, in some aspects, has a fifty percent higher capacitance density than conventional designs. For example, in some aspects the decoupling capacitance may be on the order of 200 nF to 500 nF and the capacitance density may be on the order of 400 nF to 600 nF per sq. mm.

Further, as illustrated, a first electrode 405 and second electrode 407 of the MIM capacitor 400 can be coupled to die contacts 462 of die 460 by a Cu to Cu hybrid bond 455. The Cu to Cu hybrid bond includes a die-to-wafer, where one or more dies are transferred to a final wafer and allows for the MIM capacitor 400 to be directly bonded to the die 460. The Cu to Cu hybrid bond may also include wafer to wafer or reconstituted wafer to reconstituted wafer bonding. Additionally, as illustrated, in some aspects the MIM capacitor 400 is formed in an Si substrate 431 that may be part of a Si interposer 430.

In order to fully illustrate aspects of the design of the present disclosure, methods of fabrication are presented. Other methods of fabrication are possible and discussed fabrication methods are presented only to aid understanding of the concepts disclosed herein.

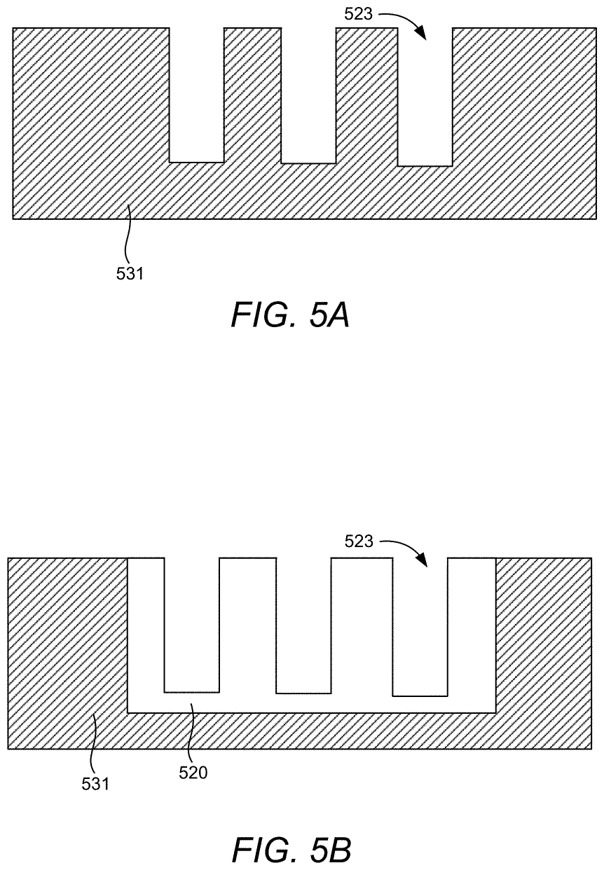

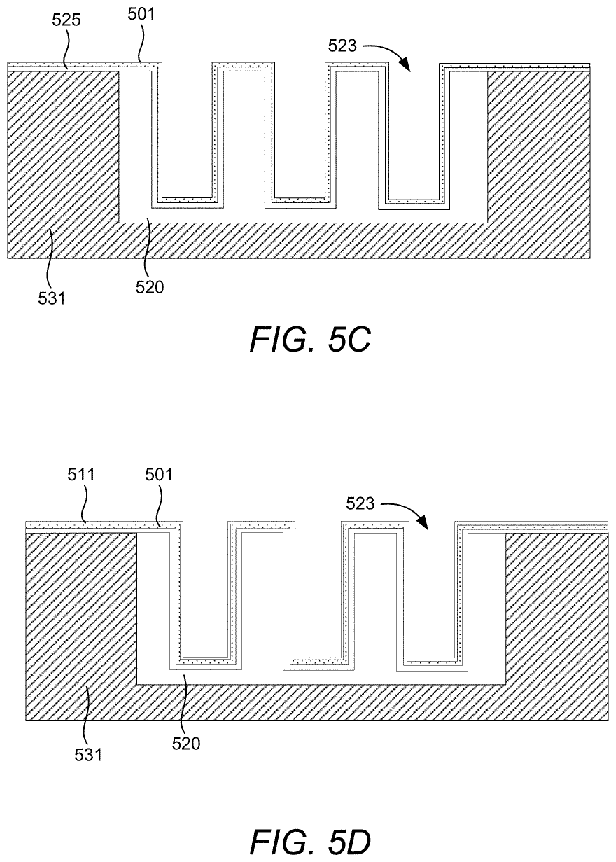

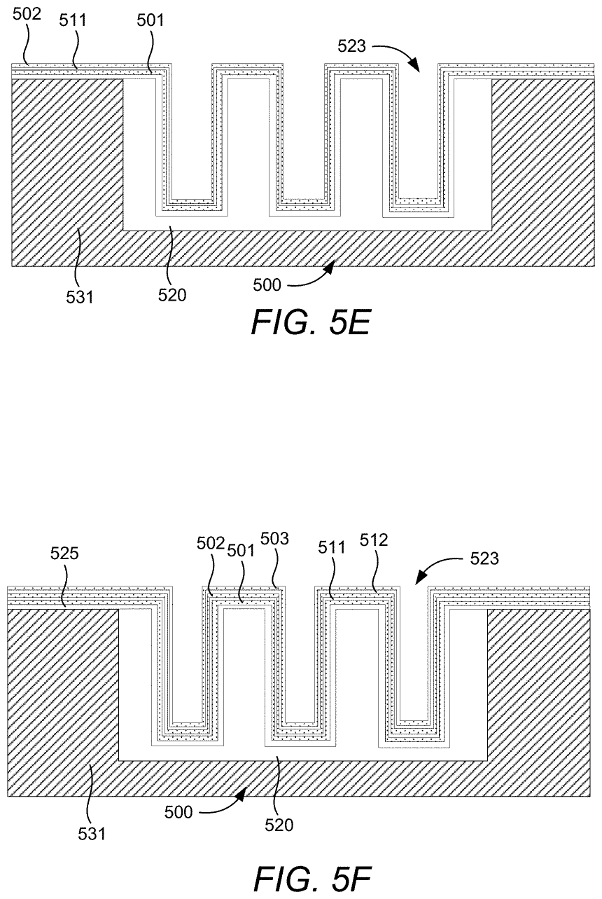

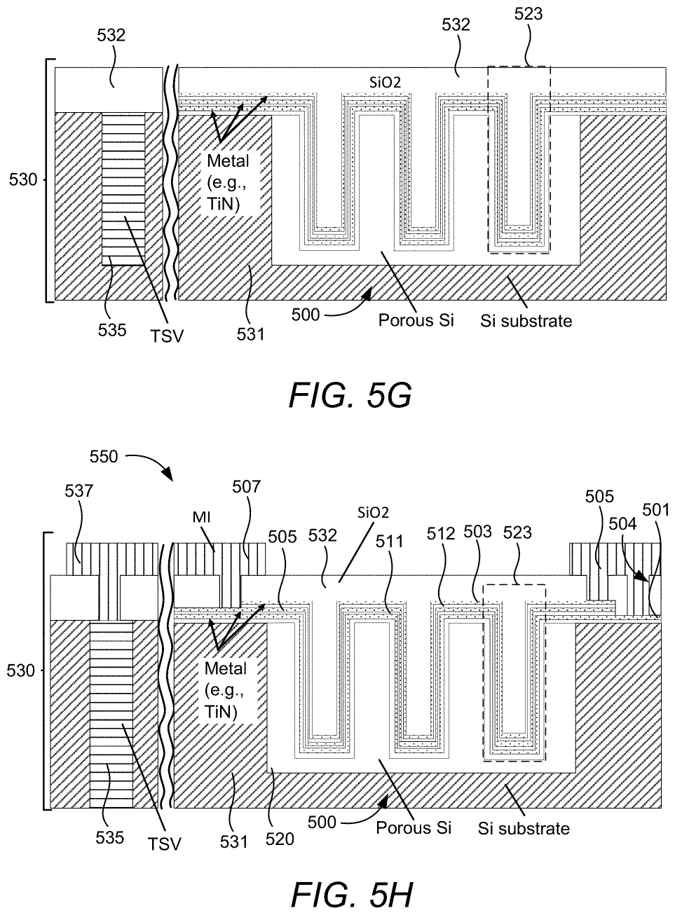

FIGS. 5A-H illustrate portions of a fabrication process in accordance with one or more aspects of the disclosure. Referring to FIG. 5A, the fabrication process can include providing a Si substrate 531, masking and etching (e.g., Bosch etch) the Si substrate 531 to form deep trenches 523.

In FIG. 5B, the process can continue with forming the porous Si a tub portion 520, which includes the trenches 523. For example, a portion of the Si substrate can be masked with a HF resistant photoresist. The tub portion 520 is not masked and can be can electrochemically etched using a given current, time, Hydrofluoric (HF) acid concentration and substrate doping. For example, the HF solution may be approximately fifty percent. For example, the electrolyte may be a one to one mixture of fifty percent HF and ethanol. A platinum rod may be used as cathode, and the Si wafer as anode. Current density is one the order of tens of milliamps (mA) per sq. cm (e.g., 75 mA/cm²). The time may the current is applied may be in the range of 20 to 60 mins. The substrate may be doped to be a P-type Si substrate 531. It will be appreciated that these values are merely provided as examples and not to limit the various aspects disclosed. Additionally, it will be appreciated that although increasing the porosity can increase the capacitance density, it will also reduce the mechanical stability of the capacitor.

In FIG. 5C, the fabrication process can continue with depositing a liner oxide layer 525 on the porous Si surface in the trenches 523. Additionally, a first plate 501 formed by a metal layer deposition, can be deposited on the oxide layer 525. The oxide layer 525 and first metal plate 501 can be deposited using thin-film deposition techniques such as atomic layer deposition (ALD) to provide for high conformance to the irregular surface of the trenches 523 in the porous Si tub portion 520. The first plate 501 may be formed from any high conductive material, such as, a metal, Titanium Nitride (TiN) or other suitable material, as described herein.

In FIG. 5D, the fabrication process can continue with depositing a first dielectric layer 511 on the first metal plate 501. The first dielectric layer 511 can be deposited using thin-film deposition techniques such as atomic layer deposition (ALD) to provide for high conformance to the irregular surface of the trenches 523 in the porous Si tub portion 520. The first dielectric layer 511 may be a high dielectric constant (high-k) dielectric material, such as Hafnium oxides (HfOₓ) or similar materials.

In FIG. 5E, the fabrication process can continue with depositing a second plate 502, formed by a metal layer deposition, deposited on the first dielectric layer 511. The second plate 502 can be deposited using thin-film deposition techniques such as atomic layer deposition (ALD) to provide for high conformance to the irregular surface of the trenches 523 in the porous Si tub portion 520. The second plate 502 may be formed from any high conductive material, such as, a metal, Titanium Nitride (TiN) or other suitable material, as described herein. It will be appreciated that the first plate 501, the first dielectric layer 511 and the second plate 502 can form a MIM capacitor 500. However, additional layers may be added to the MIM capacitor 500, as described below.

In FIG. 5F, the fabrication process can continue with depositing a second dielectric layer 512 on the second plate 502. Additionally, a third plate 503, formed by a metal layer deposition, can be deposited on the second dielectric layer 512. The second dielectric layer 512 and third plate 503 can be deposited using thin-film deposition techniques such as atomic layer deposition (ALD) to provide for high conformance to the irregular surface of the trenches 523 in the porous Si tub portion 520. The second dielectric layer 512 may be a high dielectric constant (high-k) dielectric material, such as Hafnium oxides (HfOₓ) or similar materials. The third plate 502 may be formed from any high conductive material, such as, a metal, Titanium Nitride (TiN) or other suitable material, as described herein. It will be appreciated that the first plate 501, the first dielectric layer 511, the second plate 502, the second dielectric layer 512 and the third plate 503 can form the MIM capacitor 500. However, it will be appreciated that the various aspects are not limited to a specific number of layers and additional metal and dielectric layers may be added to the MIM capacitor 500.

In FIG. 5G, the fabrication process can continue with forming one or more TSVs 535 in a further portion of the Si substrate 531 that forms part of the Si interposer 530. Further, an ILD layer 532 can be deposited on the MIM capacitor 500, which also can fill in the trenches 523. The ILD layer 532 may also extend over the further portion of the Si substrate 531 and one or more TSVs 535 that forms part of the Si interposer 530. The ILD layer may be SiO₂ or similar material.

In FIG. 5H the fabrication process can continue with forming vias 504 through the ILD layer 232 to couple the TSVs 535 and the plates 501, 502, and 503 of the MIM capacitor to a top metal layer (M1), deposited on ILD layer 532. The top metal layer (M1) can be patterned and etched to form various structures including a first electrode 505 and a second electrode 507 of the MIM capacitor 500 and an interposer top contact 537. It will be appreciated that apparatus 550 has similar features to apparatus 250, so details of each feature will not be discussed.

The cross-sectional view of the apparatus 550 included a Si interposer 530 with the MIM capacitor 500 and the Si substrate 531 forming part of the Si interposer 530. The Si interposer 530 has a plurality of interposer top contacts 537 which can be coupled by via 504 through the ILD layer 532 to TSV 535 to allow for an electrical connection through the interposer 530. Additionally, the backside of the is ground or otherwise has part of the Si substrate 531 removed to expose the TSV 535. The MIM capacitor 500 can be a decoupling capacitor, which provides for power conditioning, as discussed herein. The MIM capacitor 500 may be similar to MIM capacitors 100, 200, 300 and 400.

MIM capacitor 500 can include a plurality of trenches 523 with a porous Silicon (Si) surface formed in the plurality of trenches 523. The porous Si surface has an irregular surface on sidewalls and bottoms of the plurality of trenches 523. An oxide layer 525, first plate 502, first dielectric layer 511, second plate 502, second dielectric layer 512, and third plate 502 are conformally disposed on the porous Silicon (Si) forming the trenches 523. The first electrode 505 of the MIM capacitor 500 can be coupled to the first plate 501 and the third plate 503 by one or more vias 504 that extend through the ILD layer 532 that covers the MIM capacitor 500. The second electrode 507 of the MIM capacitor 500 can be coupled to the second plate 502 by one or more vias 504 that extend through the ILD layer 532.

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

In accordance with the various aspects disclosed herein, at least one aspect includes an apparatus including: a metal-insulator-metal (MIM) capacitor (e.g., 100, 200, 300, 400 and 500) having a plurality of trenches, a porous Silicon (Si) surface formed in the plurality of trenches formed in an Si substrate. The porous Si surface has an irregular surface on sidewalls and bottoms of the plurality of trenches. An oxide layer is conformally disposed on the porous Si surface. A first plate is conformally disposed on the oxide layer. A first dielectric layer is conformally disposed on the first plate. A second plate is conformally disposed on the first dielectric. The first plate, the first dielectric layer, and the second plate, each have an irregular surface that generally conforms to the irregular surface of the porous Si surface. The various aspects disclosed have various technical advantages over conventional designs. At least some features of the various aspects, such as the plates and dielectric layers of the MIM capacitor conformally disposed on the porous Si surface provide for increased capacitance density and reduced size for a decoupling capacitor that can be directly attached to a die, as discussed herein. Other technical advantages will be recognized from various aspects disclosed herein and these technical advantages are merely provided as examples and should not be construed to limit any of the various aspects disclosed herein.

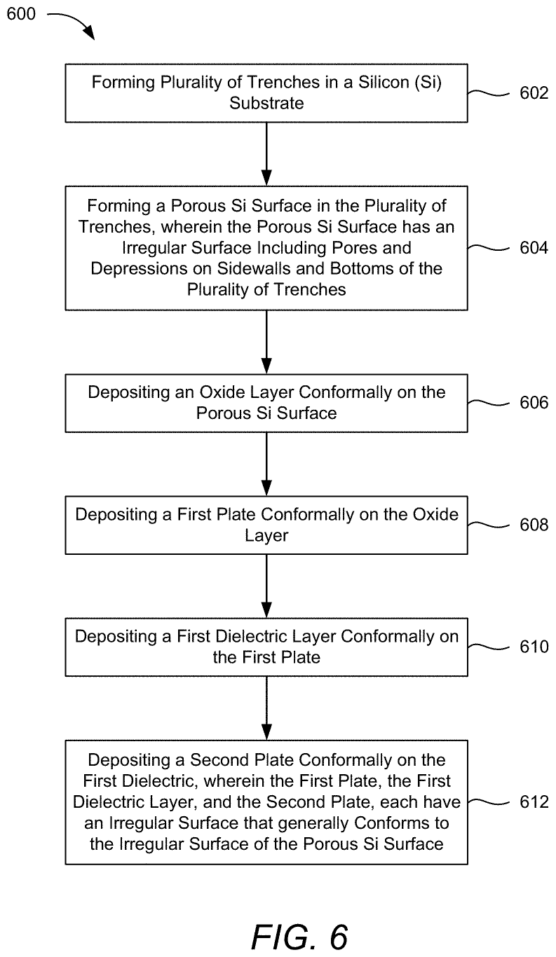

It will be appreciated from the foregoing that there are various methods for fabricating devices including the MIM capacitors and Si interposers disclosed herein. FIG. 6 illustrates a flowchart of a method 600 for fabricating an apparatus including a MIM capacitor (e.g., 100, 200, 300, 400 and 500). The process can begin in block 602 with forming a plurality of trenches (e.g., 123, 223, 523) in a Silicon (Si) substrate (e.g., 131, 231, etc.). The process continues in block 604 with forming a porous Si surface (e.g., 121) in the plurality of trenches, wherein the porous Si surface has an irregular surface on sidewalls and bottoms of the plurality of trenches. The process continues in bock 606 with depositing an oxide layer (e.g., 125, 225, etc.) conformally on the porous Si surface. The process continues in bock 608 with depositing a first plate (101, 201, etc.) conformally on the oxide layer. The process continues in bock 610 with depositing a first dielectric layer (e.g., 111, 211, etc.) conformally on the first plate. The process continues in bock 612 with depositing a second plate conformally on the first dielectric, wherein the first plate, the first dielectric layer, and the second plate, each have an irregular surface that generally conforms to the irregular surface of the porous Si surface.

It will be appreciated from the foregoing disclosure that additional processes for fabricating the various aspects disclosed herein will be apparent to those skilled in the art and a literal rendition of the processes discussed above will not be provided or illustrated in the included drawings. It will be appreciated that the sequence of the fabrication processes are not necessarily in any order and later processes may be discussed earlier to provide an example of the breadth of the various aspects disclosed.

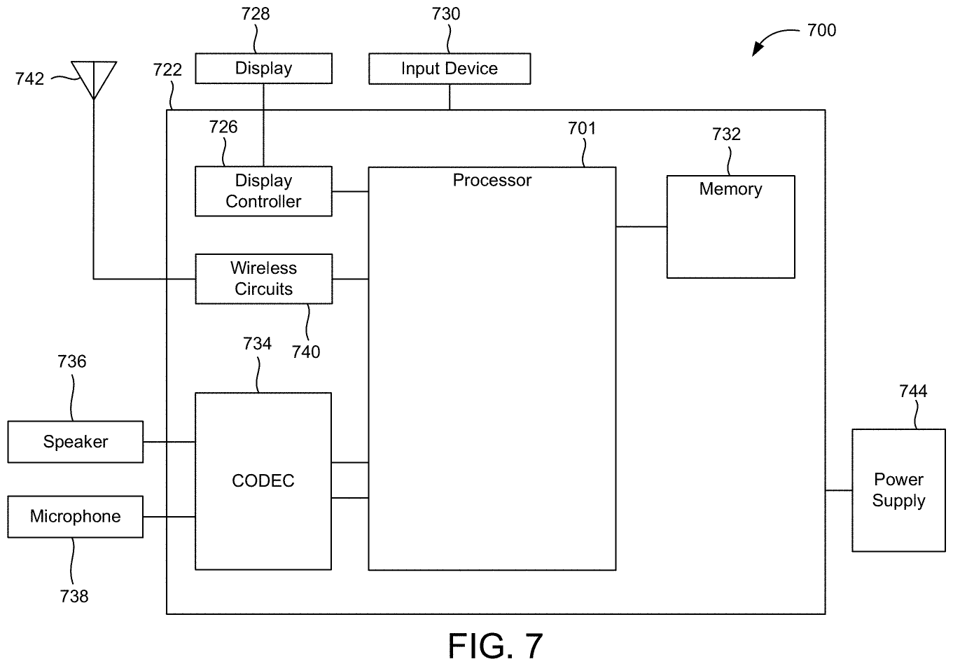

FIG. 7 illustrates an exemplary mobile device in accordance with some examples of the disclosure. Referring now to FIG. 7, a block diagram of a mobile device that is configured according to exemplary aspects is depicted and generally designated mobile device 700. In some aspects, mobile device 700 may be configured as a wireless communication device. As shown, mobile device 700 includes processor 701. Processor 701 may be communicatively coupled to memory 732 over a link, which may be a die-to-die or chip-to-chip link. Mobile device 700 also includes display 728 and display controller 726, with display controller 726 coupled to processor 701 and to display 728.

In some aspects, FIG. 7 may include coder/decoder (CODEC) 734 (e.g., an audio and/or voice CODEC) coupled to processor 701; speaker 736 and microphone 738 coupled to CODEC 734; and wireless circuits 740 (which may include a modem, memory and/or other SoC device which may be implemented using one or more decoupling capacitors and Si interposers, as disclosed herein) coupled to wireless antenna 742 and to processor 701.

In a particular aspect, where one or more of the above-mentioned blocks are present, processor 701, display controller 726, memory 732, CODEC 1234, and wireless circuits 740 can be included in a system-in-package or system-on-chip device 722 which may be include one or more of the MIM capacitors or Si interposers with one or more MIM capacitors disclosed herein. Input device 730 (e.g., physical or virtual keyboard), power supply 744 (e.g., battery), display 728, input device 730, speaker 736, microphone 738, wireless antenna 742, and power supply 744 may be external to system-on-chip device 722 and may be coupled to a component of system-on-chip device 722, such as an interface or a controller.

It should be noted that although FIG. 7 depicts a mobile device 700, processor 701 and memory 732 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

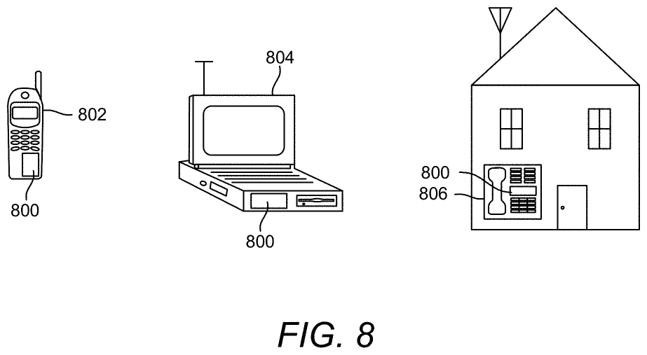

FIG. 8 illustrates various electronic devices that may be integrated with any of the aforementioned integrated device or semiconductor device accordance with various examples of the disclosure. For example, a mobile phone device 802, a laptop computer device 804, and a fixed location terminal device 806 may each be consider generally user equipment (UE) and may include a device 800 including one or more of the MIM capacitors or Si interposers with one or more MIM capacitors as described herein. The device 800 may be, for example, any of the integrated circuits, dies, integrated devices, integrated device packages, integrated circuit devices, device packages, integrated circuit (IC) packages, package-on-package devices described herein. The devices 802, 804, 806 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., register-transfer level (RTL), Geometric Data Stream (GDS) Gerber, and the like) stored on computer-readable media. Some or all such files may be provided to fabrication handlers who fabricate devices based on such files. Resulting products may include semiconductor wafers that are then cut into semiconductor die and packaged into semiconductor packages, integrated devices, system-on-chip devices and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature or function or incorporated in several components, processes, or functions. Additional elements, components, processes, and/or functions may also be added without departing from the disclosure. It should also be noted that FIGS. 1-8 and corresponding description in the present disclosure are not limited to dies and/or ICs. In some implementations, FIGS. 1-8 and the corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:

Clause 1. An apparatus comprising a metal-insulator-metal (MIM) capacitor, the MIM capacitor comprising: a plurality of trenches in a Silicon (Si) substrate; a porous Si surface formed in the plurality of trenches, wherein the porous Si surface has an irregular surface on sidewalls and bottoms of the plurality of trenches; an oxide layer conformally disposed on the porous Si surface; a first plate conformally disposed on the oxide layer; a first dielectric layer conformally disposed on the first plate; and a second plate conformally disposed on the first dielectric, wherein the first plate, the first dielectric layer, and the second plate, each have an irregular surface that generally conforms to the irregular surface of the porous Si surface.

Clause 2. The apparatus of clause 1, further comprising: a second dielectric layer conformally disposed on the second plate; and a third plate conformally disposed on the second dielectric, wherein the second dielectric layer and the third plate, each have an irregular surface that generally conforms to the irregular surface of the porous Si surface.

Clause 3. The apparatus of any of clauses 1 to 2, further comprising: a tub portion of the Si substrate containing the plurality of trenches, wherein the tub portion is a porous Si material.

Clause 4. The apparatus of any of clauses 1 to 3, further comprising: a die having a plurality of die contacts, wherein two of the plurality of die contacts are coupled to electrodes of the MIM capacitor.

Clause 5. The apparatus of clause 4, wherein the plurality of die contacts are coupled to the electrodes of the MIM capacitor by a Copper to Copper hybrid bond.

Clause 6. The apparatus of any of clauses 4 to 5, further comprising: a Si interposer comprising the Si substrate.

Clause 7. The apparatus of clause 6, wherein the Si interposer further comprises at least one through silicon via (TSV), wherein the at least one TSV is electrically coupled to the die through at least one of the plurality of die contacts.

Clause 8. The apparatus of clause 7, wherein the plurality of die contacts are coupled to the electrodes of the MIM capacitor by a Copper to Copper hybrid bond.

Clause 9. The apparatus of any of clauses 7 to 8, further comprising: a second die having a plurality of second die contacts, wherein at least one additional TSV of the Si interposer is electrically coupled to the second die by at least one of the plurality of second die contacts.

Clause 10. The apparatus of clause 9, further comprising: a second MIM capacitor, wherein the second MIM capacitor is formed in the Si substrate of the Si interposer and wherein the second MIM capacitor is electrically coupled to the second die by at least two of the plurality of second die contacts being electrically coupled to two electrodes of the second MIM capacitor.

Clause 11. The apparatus of clause 10, wherein the die and the second die are coupled to the Si interposer by a Copper to Copper hybrid bond.

Clause 12. The apparatus of any of clauses 1 to 11, wherein the MIM capacitor has a thickness of less than 30 micrometers.

Clause 13. The apparatus of any of clauses 1 to 12, wherein the apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station and a device in an automotive vehicle.

Clause 14. A method for fabricating an apparatus comprising a metal-insulator-metal (MIM) capacitor, the method comprising: forming plurality of trenches in a Silicon (Si) substrate; forming a porous Si surface in the plurality of trenches, wherein the porous Si surface has an irregular surface on sidewalls and bottoms of the plurality of trenches; depositing an oxide layer conformally on the porous Si surface; depositing a first plate conformally on the oxide layer; depositing a first dielectric layer conformally on the first plate; and depositing a second plate conformally on the first dielectric, wherein the first plate, the first dielectric layer, and the second plate, each have an irregular surface that generally conforms to the irregular surface of the porous Si surface.

Clause 15. The method of clause 14, further comprising: depositing a second dielectric layer conformally on the second plate; and depositing a third plate conformally on the second dielectric, wherein the second dielectric layer and the third plate, each have an irregular surface that generally conforms to the irregular surface of the porous Si surface.

Clause 16. The method of any of clauses 14 to 15, further comprising: forming a tub portion of the Si substrate containing the plurality of trenches, wherein the tub portion is a porous Si material.

Clause 17. The method of any of clauses 14 to 16, further comprising: coupling a die having a plurality of die contacts to the MIM capacitor, wherein two of the plurality of die contacts are coupled to electrodes of the MIM capacitor.

Clause 18. The method of clause 17, wherein the plurality of die contacts are coupled to the electrodes of the MIM capacitor by a Copper to Copper hybrid bond.

Clause 19. The method of any of clauses 17 to 18, further comprising: forming a Si interposer comprising the Si substrate.

Clause 20. The method of clause 19, wherein forming the Si interposer further comprises forming at least one through silicon via (TSV), wherein the at least one TSV is electrically coupled to the die through at least one of the plurality of die contacts.

Clause 21. The method of clause 20, wherein the plurality of die contacts are coupled to the electrodes of the MIM capacitor by a Copper to Copper hybrid bond.

Clause 22. The method of any of clauses 20 to 21, further comprising: coupling a second die having a plurality of second die contacts to the Si interposer, wherein at least one additional TSV of the Si interposer is electrically coupled to the second die by at least one of the plurality of second die contacts.

Clause 23. The method of clause 22, further comprising: forming a second MIM capacitor in the Si substrate of the Si interposer and wherein the second MIM capacitor is electrically coupled to the second die by at least two of the plurality of second die contacts being coupled to two electrodes of the second MIM capacitor.

Clause 24. The method apparatus of clause 23, wherein the die and the second die are coupled to the Si interposer by a Copper to Copper hybrid bond.

Clause 25. The method of any of clauses 14 to 24, wherein the MIM capacitor has a thickness of less than 30 micrometers.

Clause 26. The method of any of clauses 14 to 25, wherein the apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station and a device in an automotive vehicle.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. An apparatus comprising a metal-insulator-metal (MIM) capacitor, the MIM capacitor comprising:
a plurality of trenches in a Silicon (Si) substrate;
a porous Si surface formed in the plurality of trenches, wherein the porous Si surface has an irregular surface on sidewalls and bottoms of the plurality of trenches;
an oxide layer conformally disposed on the porous Si surface;
a first plate conformally disposed on the oxide layer;
a first dielectric layer conformally disposed on the first plate; and
a second plate conformally disposed on the first dielectric, wherein the first plate, the first dielectric layer, and the second plate, each have an irregular surface that generally conforms to the irregular surface of the porous Si surface.

2. The apparatus of claim 1, further comprising:
a second dielectric layer conformally disposed on the second plate; and
a third plate conformally disposed on the second dielectric, wherein the second dielectric layer and the third plate, each have an irregular surface that generally conforms to the irregular surface of the porous Si surface.

3. The apparatus of claim 1, further comprising:
a tub portion of the Si substrate containing the plurality of trenches, wherein the tub portion is a porous Si material.

4. The apparatus of claim 1, further comprising:
a die having a plurality of die contacts, wherein two of the plurality of die contacts are coupled to electrodes of the MIM capacitor.

5. The apparatus of claim 4, wherein the plurality of die contacts are coupled to the electrodes of the MIM capacitor by a Copper to Copper hybrid bond.

6. The apparatus of claim 4, further comprising:
a Si interposer comprising the Si substrate.

7. The apparatus of claim 6, wherein the Si interposer further comprises at least one through silicon via (TSV), wherein the at least one TSV is electrically coupled to the die through at least one of the plurality of die contacts.

8. The apparatus of claim 7, wherein the plurality of die contacts are coupled to the electrodes of the MIM capacitor by a Copper to Copper hybrid bond.

9. The apparatus of claim 7, further comprising:
a second die having a plurality of second die contacts, wherein at least one additional TSV of the Si interposer is electrically coupled to the second die by at least one of the plurality of second die contacts.

10. The apparatus of claim 9, further comprising:
a second MIM capacitor, wherein the second MIM capacitor is formed in the Si substrate of the Si interposer and wherein the second MIM capacitor is electrically coupled to the second die by at least two of the plurality of second die contacts being electrically coupled to two electrodes of the second MIM capacitor.

11. The apparatus of claim 10, wherein the die and the second die are coupled to the Si interposer by a Copper to Copper hybrid bond.

12. The apparatus of claim 1, wherein the MIM capacitor has a thickness of less than 30 micrometers.

13. The apparatus of claim 1, wherein the apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station and a device in an automotive vehicle.

14. A method for fabricating an apparatus comprising a metal-insulator-metal (MIM) capacitor, the method comprising:
forming plurality of trenches in a Silicon (Si) substrate;
forming a porous Si surface in the plurality of trenches, wherein the porous Si surface has an irregular surface on sidewalls and bottoms of the plurality of trenches;
depositing an oxide layer conformally on the porous Si surface;
depositing a first plate conformally on the oxide layer;
depositing a first dielectric layer conformally on the first plate; and
depositing a second plate conformally on the first dielectric, wherein the first plate, the first dielectric layer, and the second plate, each have an irregular surface that generally conforms to the irregular surface of the porous Si surface.

15. The method of claim 14, further comprising:
depositing a second dielectric layer conformally on the second plate; and
depositing a third plate conformally on the second dielectric, wherein the second dielectric layer and the third plate, each have an irregular surface that generally conforms to the irregular surface of the porous Si surface.

16. The method of claim 14, further comprising:
forming a tub portion of the Si substrate containing the plurality of trenches, wherein the tub portion is a porous Si material.

17. The method of claim 14, further comprising:
coupling a die having a plurality of die contacts to the MIM capacitor, wherein two of the plurality of die contacts are coupled to electrodes of the MIM capacitor.

18. The method of claim 17, wherein the plurality of die contacts are coupled to the electrodes of the MIM capacitor by a Copper to Copper hybrid bond.

19. The method of claim 17, further comprising:
forming a Si interposer comprising the Si substrate.

20. The method of claim 19, wherein forming the Si interposer further comprises forming at least one through silicon via (TSV), wherein the at least one TSV is electrically coupled to the die through at least one of the plurality of die contacts.

21. The method of claim 20, wherein the plurality of die contacts are coupled to the electrodes of the MIM capacitor by a Copper to Copper hybrid bond.

22. The method of claim 20, further comprising:
coupling a second die having a plurality of second die contacts to the Si interposer, wherein at least one additional TSV of the Si interposer is electrically coupled to the second die by at least one of the plurality of second die contacts.

23. The method of claim 22, further comprising:
forming a second MIM capacitor in the Si substrate of the Si interposer and wherein the second MIM capacitor is electrically coupled to the second die by at least two of the plurality of second die contacts being coupled to two electrodes of the second MIM capacitor.

24. The method apparatus of claim 23, wherein the die and the second die are coupled to the Si interposer by a Copper to Copper hybrid bond.

25. The method of claim 14, wherein the MIM capacitor has a thickness of less than 30 micrometers.

26. The method of claim 14, wherein the apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, an access point, a base station and a device in an automotive vehicle.
